(19) United States
(12) Patent Application Publication
(10) Pub. No.: US 2017/0250710 A1
(43) Pub. Date: Aug. 31, 2017

(54) METHOD AND DEVICE FOR CALCULATING A CRC CODE IN PARALLEL

(71) Applicant: Telefonaktiebolaget LM Ericsson (publ), Stockholm (SE)

(72) Inventors: Kazunori ASANAKA, Tottori (JP); Christer AALTO, Tokyo (JP)

(21) Appl. No.: 15/516,401

(22) PCT Filed: Oct. 3, 2014
(86) PCT No.: PCT/EP2014/071249

§ 371 Date: Apr. 1, 2017

(51) Int. Cl. H03M 13/09; H03M 13/00

(52) U.S. Cl. CPC H03M 13/091; H03M 13/617

(57) ABSTRACT

The disclosure relates to a method performed in a cyclic redundancy check, CRC, device for calculating, based on a generator polynomial G(x), a CRC code for a message block. The method comprises receiving n segments of the message block in forward order or in reverse order, wherein at least one segment is received in reverse order; calculating for each of the n segments a respective segment CRC code based on the generator polynomial G(x), wherein each segment CRC is calculated according to the received order of the segment; aligning each of the n segment CRC codes; and calculating the CRC code for the message block by adding together each of the aligned n segment CRC codes. The disclosure also relates to a device, computer program and computer program product.

### TECHNICAL FIELD

The technology disclosed herein relates generally to the field of error-detecting codes, and in particular to cyclic redundancy check algorithms.

### BACKGROUND

A cyclic redundancy check (CRC) is an error-detecting code, wherein the algorithm is based on cyclic codes. CRC is used for instance in digital networks for detecting changes to raw data. A sender generates a check value, a CRC checksum, and appends it to a block of data. The CRC checksum is based on a reminder of a polynomial division of the contents of the block of data and a receiver can check the received block of data by repeating the calculation. If, upon a comparison, check values do not match, data corruption is detected.

Common CRC algorithms are expressed as polynomial division on Galois Field of two elements GF(2) (the elements usually denoted 0 and 1) and the calculation is performed bit by bit. A polynomial in GF(2) is a polynomial in a single variable x the coefficients of which are 0 or 1. The calculation of bit by bit requires a high amount of processing time because only one bit can be processed per clock cycle. A method for calculating a number of consecutive bits per clock cycle has therefore been introduced for high speed applications, wherein CRC bits are processed in parallel instead of serially. For example, one byte of data is processed by cycle from the first byte of the message to the last byte of the message.

However, also such parallel processing method entails some drawbacks. The computational complexity of the CRC algorithm, i.e. the logic depth, increases and makes the CRC algorithm more difficult to run at a high clock speed, in particular when the number of parallel bits is increased. If, for example, 1024 bits of data are processed per cycle, then the next state of a CRC generator is determined by a large combinatorial logic which takes 1024 bits of input. Further, in order to process the message sub-blocks on arrival, the bits need to be stored temporarily and they need to be reordered, since this method depends on the input order.

In order to solve these problems, a method to split the CRC calculation into multiple message sub-blocks, also denoted segments, has been introduced. The input data is divided into multiple segments and each segment can be assigned to a respective CRC engine. The CRC checksum can then be assembled using the output results of the CRC engines. This scheme also enables out-of-order calculation method of CRC checksum with sub-block level.

Aside from the above methods, a CRC checking method for the reverse order input of codeword, which comprises a data message and CRC checksum, using a reverse (or reciprocal) polynomial is known.

FIG. 1 illustrates the computing with a generator polynomial G(D) (arrows A1 and A2) and computing with reverse generator polynomial G^{R}(D) (arrows B1 and B2), respectively. As mentioned above, a codeword 1 comprises a message 2 and an appended CRC checksum 3. The generator polynomial G(D) is given by:

G(D)=D^{L}+g_{L-1}D^{L-1}+g_{L-2}D^{L-2}+ . . . +g₂D²+g₁D¹+1

Computing with the generator polynomial G(D) over the codeword 1 results in 0 (arrow A), while computing with the polynomial G(D) over the message 2 results in the CRC checksum 3 (arrow A2), which is L bits long.

The reverse generator polynomial G^{R}(D) is given by:

G^{R}(D)=D^{L}+g₁D^{L-1}+g₂D^{L-2}+ . . . +g_{L-2}D²+g_{L-1}D¹+1

Computing with the reverse polynomial G^{R}(D) over the codeword 1 excluding the first L bits of the message 2 in the reverse order results in the reversing of the first L bits of the message 2 (arrow B1), where L is the CRC checksum length. Computing with the reverse polynomial G^{R}(D) over the codeword 1 in the reverse order results in 0 (arrow B2).

The methods that have been described all entail shortcomings. For instance, when the input data is stored into memory and the computation is performed with a forward order algorithm, this causes an undesired extra latency for the computing of CRC and also entails storage requirements.

When splitting the CRC checksum into small segments, e.g. into segments of 1 bit, and computing partial CRC checksums and combining with phase shift using an out of order incremental CRC scheme, a phase shifted calculation needs to be performed for each sub-block with small length in order to align at the end of the target block by multiplying a power of matrix. A drawback is that the computation of a power of matrix is expensive in terms of processing.

### SUMMARY

The methods using the properties described in relation to FIG. 1 enables only checking CRC in the reverse order input, while generating CRC in the reverse order input is not possible.

The drawback of processing intense matrix computations for the earlier described splitting of CRC into small segments has been identified and analyzed by the inventors of the present application. The computationally intensive algorithm results from the scheme being able to shift the phase only forward, not backward.

It would be desirable to compute CRC with mixture of forward and reverse order input but there is no known algorithm to handle this. This would alleviate storage need as well as simplify hardware implementation.

An object of the present disclosure is to solve or at least alleviate at least one of the above mentioned problems.

The object is according to a first aspect achieved by a method performed in a cyclic redundancy check, CRC, device for calculating, based on a generator polynomial, a CRC code for a message block. The method comprises: receiving n segments of the message block in forward order or in reverse order, wherein at least one segment is received in reverse order; calculating for each of the n segments a respective segment CRC code based on the generator polynomial, wherein each segment CRC is calculated according to the received order of the segment; aligning each of the n segment CRC codes; and calculating the CRC code for the message block by adding together each of the aligned n segment CRC codes.

The method enables reverse order CRC generation as well as reverse order CRC check. The method further enables a bit sequence to be received in a mixture of forward and reverse order whereby for instance latency related to temporary storage followed by post-processing of the bit sequence in natural order is avoided.

The object is according to a second aspect achieved by a device for calculating, based on a generator polynomial, a CRC code for a message block. The device is configured to: receive n segments of the message block in forward order or in reverse order, wherein at least one segment is received in reverse order; calculate for each of the n segments a respective segment CRC code based on the generator polynomial, wherein each segment is calculated according to the received order of the segment; align each of the n segment CRC codes; and calculate the CRC code for the message block by adding together each of the aligned n segment CRC codes.

The object is according to a third aspect achieved by a computer program for a device for calculating cyclic redundancy check, CRC, codes. The computer program comprises computer program code, which, when executed on at least one processor on the device causes the device to perform the method as above.

The object is according to a fourth aspect achieved by a computer program product comprising a computer program as above and a computer readable means on which the computer program is stored.

Further features and advantages of the present disclosure will become clear upon reading the following description and the accompanying drawings.

### BRIEF DESCRIPTION OF THE DRAWINGS

FIG. 1 illustrates a reverse order CRC check with reverse polynomial.

FIG. 2 illustrates a CRC8 generator for forward order input.

FIG. 3 illustrates solving of a recurrence equation.

FIG. 4 illustrates a multiple-input bit CRC generator.

FIG. 5 illustrates splitting calculation with forward order input.

FIG. 6 is a graphical illustration of calculation of split of CRC.

FIG. 7 illustrates solving of recurrence equation.

FIG. 8 illustrates alignment correction of CRC in reverse order calculation.

FIG. 9 is a flow chart for CRC generation with reverse order input block.

FIG. 10 illustrates a CRC8 generator for reverse order input.

FIG. 11 is a flow chart for CRC generation with reverse order input block.

FIG. 12 is a CRC8 generator for reverse order input.

FIG. 13 illustrates a generic multiple-input bits CRC generator core supporting both forward and reverse modes.

FIG. 14 illustrates combining of segment CRCs with mixture of forward and reverse order calculations.

FIG. 15 illustrates hardware for combining segment CRCs with phase shift.

FIG. 16 illustrates hardware accelerator for computing a power of matrix.

FIG. 17 shows a comparison of state transitions of CRC registers.

FIG. 18 illustrates a flow chart over steps of a method in a CRC engine in accordance with the present disclosure.

FIG. 19 illustrates schematically a device for implementing embodiments of the present disclosure.

### DETAILED DESCRIPTION

In the following description, for purposes of explanation and not limitation, specific details are set forth such as particular architectures, interfaces, techniques, etc. in order to provide a thorough understanding. In other instances, detailed descriptions of well-known devices, circuits, and methods are omitted so as not to obscure the description with unnecessary detail. Same reference numerals refer to same or similar elements throughout the description.

Briefly, the present disclosure provides a method to compute CRC with the reverse order or mixture of forward and reverse order of inputs.

In an aspect of the present disclosure, a target data block is fed to a CRC generator core in a reverse order and unaligned CRC is calculated. In this calculation, the state transition of the CRC generator is expressed with a linear operation with the inverse of the matrix which is used to express the state transition of CRC generator for forward (conventional) order of inputs. This inverse of the matrix may be easily obtained by reordering the elements of the original matrix. Then the phase shift of CRC is performed by multiplying a power of matrix and the alignment of CRC is corrected. The computation of a power of matrix is required only once per target block, reducing processing time and required processing capacity.

By splitting the calculation into multiple segments, calculation with a multi-core engine can be performed. Further, the handling of a mixture of forward and reverse order calculations is enabled. The partial/unaligned CRC is calculated for each segment and the final (aligned) CRC may be combined with the phase shift of partial/unaligned CRCs.

By enabling CRC to be calculated on-the-fly over a bit sequence received in a mixture of forward and reverse order, as allowed by the present disclosure, it is possible to avoid the latency as result of temporary storage followed by post-processing of the bit sequence in natural (forward) order.

As a particular example, in Long Term Evolution (LTE) turbo decoders, the code block CRC can be utilized as an early-stop criterion, reducing power consumption and allowing management of a total iteration budget over several code blocks. High throughput turbo decoder implementations require splitting the code blocks in segments, also known as windows, which are processed in parallel. As the number of windows that is used increases in order to achieve ever higher throughputs, performance losses due to the windowing also increase. Processing for instance even and odd windows in opposite directions, as may be done according to the present disclosure, at least partially mitigates the performance losses. In such turbo decoder, for enabling the partial CRC calculations (one per window) it must be possible to calculate CRC on-the-fly in both natural and reverse order to achieve lowest possible latency.

The latency savings provided according to aspects of the present disclosure, correspond to a quarter-iteration of processing. As a particular example, in worst total power consuming scenarios 4.75% can be saved, assuming a typical 5 iterations per code block in these scenarios. In ideal signal-to-noise ratio (SNR) conditions where only one turbo iteration is needed, a power reduction of 20% can be achieved. Avoiding the latency also allows reducing the peak operating frequency with 4.75% with preserved error correction performance, alternatively gaining in performance at original frequency.

In the above exemplary use case, the (2n+1)-th segment is assumed to be computed in the forward order and the (2n+2)-th segment is assumed to be computed in the reverse order, where n is a non-negative integer.

In the present disclosure, at least the following five methods for CRC calculation are mentioned.
Method F (known art): Forward order CRC check or generation with polynomial.
Method R-0 (known art): Reverse order CRC check method with reverse polynomial. This method is only for CRC check and CRC generation is not possible.
Method R-1 (Provided by the present disclosure): Reverse order CRC check or generation method with pure reverse calculation of Method F.
Method R-2 (Provided by the present disclosure): Reverse order CRC check or generation method where the internal state is modified from Method R-1.
Method M (Provided by the present disclosure): Mixed order CRC check or generation method, which is comprised of Method F and Method R-2.

### CRC Generator Model

FIG. 2 illustrates an implementation of a CRC8 generator 10 for forward order input (most significant bit first). As is well known within the art, a generator polynomial has to be defined for a CRC checksum. The CRC8 in 3^{rd} Generation Partnership Project (3GPP TS25.212 or TS36.212) is used as a simple example for the purpose of illustration. Another example of a generator polynomial comprises D¹⁶+D¹²+D⁵+1, which may be used for generating a 16-bit CRC checksum. The generator polynomial is the divisor in a polynomial long division taking a message, for which the CRC checksum is to be calculated, as the dividend and wherein the quotient is discarded and the reminder becomes the desired CRC checksum.

Thus, referring still to FIG. 2, bits d(i) representing bits of the message for which the CRC checksum is to be calculated are input to an exclusive or (XOR) operation, together with a corresponding position of the CRC divisor, i.e. of the generator polynomial. The first of such XOR operations is indicated at reference numeral 11.

The CRC8 generator to thereby generates an 8-bit CRC checksum. The cyclic generator polynomial G_{CRC8} for this particular CRC8 for which the circuit diagram illustrated in FIG. 2 is applicable, is expressed as:

G_{CRC8}(D)=D⁸+D⁷+D⁴+D³+D+1.

The circuit diagram of FIG. 2 is therefore implementing five exclusive or (XOR) operations (one of which is indicated at reference numeral 13). The implementation is conventionally done by a shift register, when implemented in hardware, as is also well known within the art. The resulting CRC (indicated at reference numeral 12) is then the reminder of the division of the message by the generator polynomial G_{CRC8} and is appended to the message.

A state transition equation in general is an equation whose solution gives the state for a certain time t.

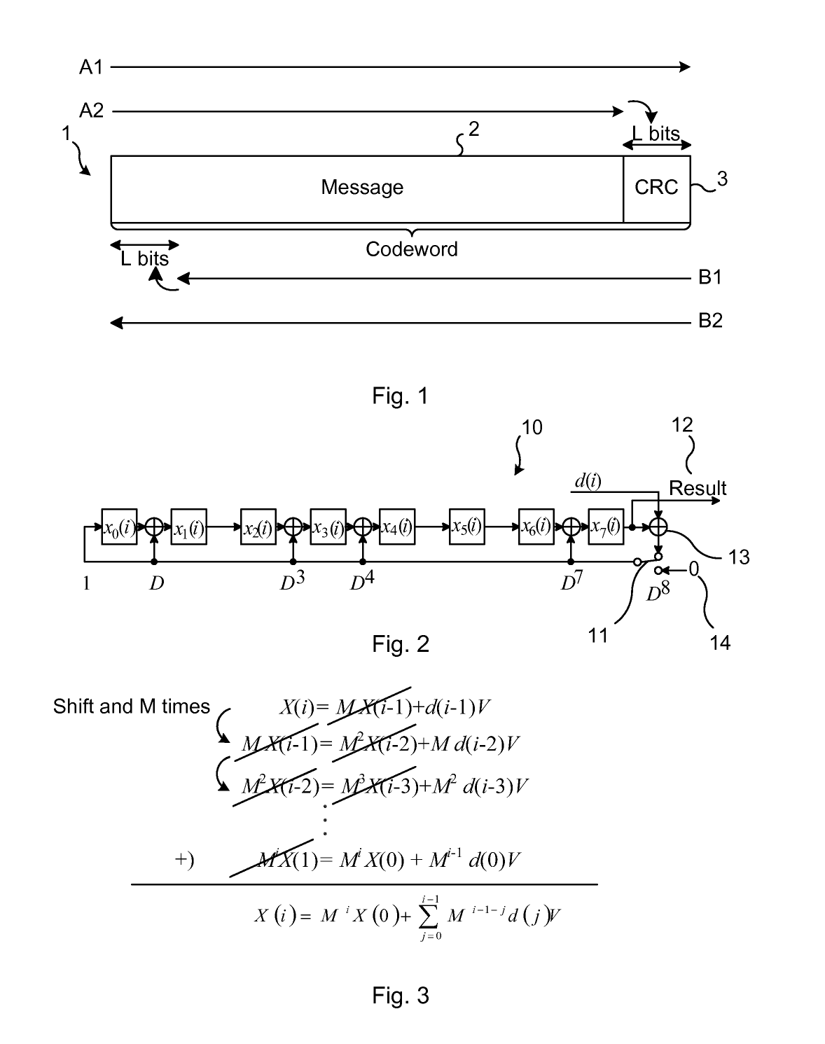

For the CRC8, the state transition equation for the circuit of FIG. 2 is expressed as:

$$\begin{matrix} ( Equation 1 ) & \\ [ \begin{matrix}{x}_{0} ( i + 1 ) \\ {x}_{1} ( i + 1 ) \\ {x}_{2} ( i + 1 ) \\ {x}_{3} ( i + 1 ) \\ {x}_{4} ( i + 1 ) \\ {x}_{5} ( i + 1 ) \\ {x}_{6} ( i + 1 ) \\ {x}_{7} ( i + 1 )\end{matrix} ] = [ \begin{matrix}0 & 0 & 0 & 0 & 0 & 0 & 0 & 1 \\ 1 & 0 & 0 & 0 & 0 & 0 & 0 & 1 \\ 0 & 1 & 0 & 0 & 0 & 0 & 0 & 0 \\ 0 & 0 & 1 & 0 & 0 & 0 & 0 & 1 \\ 0 & 0 & 0 & 1 & 0 & 0 & 0 & 1 \\ 0 & 0 & 0 & 0 & 1 & 0 & 0 & 0 \\ 0 & 0 & 0 & 0 & 0 & 1 & 0 & 0 \\ 0 & 0 & 0 & 0 & 0 & 0 & 1 & 1\end{matrix} ] [ \begin{matrix}{x}_{0} ( i ) \\ {x}_{1} ( i ) \\ {x}_{2} ( i ) \\ {x}_{3} ( i ) \\ {x}_{4} ( i ) \\ {x}_{5} ( i ) \\ {x}_{6} ( i ) \\ {x}_{7} ( i )\end{matrix} ] + d ( i ) [ \begin{matrix}1 \\ 1 \\ 0 \\ 1 \\ 1 \\ 0 \\ 0 \\ 1\end{matrix} ] & ( modulo 2 )\end{matrix}$$

where
d(i): Input data at clock cycle #i, wherein the input data may be either a message or a codeword (compare reference numeral 2 and 1, respectively, of FIG. 1).
xⱼ(i): The state of CRC generator (shift register) #j at clock cycle #i.

(Equation 1) can be generalized for any CRC algorithm as:

X(i+1)=MX(i)+d(i)V(modulo 2) (Equation 2)

where
V: is a constant vector with length L determined by the CRC algorithm used.
L: is an integer representing CRC size. For 3GPP, L may for instance be 8, 12, 16 or 24.
M: is an L by L constant matrix determined by the CRC algorithm used.
X(i): is a vector representing the state of CRC generator registers at clock cycle #i.

In the case of the above example for CRC8 generator polynomial, the following would be used

$$M = [ \begin{matrix}0 & 0 & 0 & 0 & 0 & 0 & 0 & 1 \\ 1 & 0 & 0 & 0 & 0 & 0 & 0 & 1 \\ 0 & 1 & 0 & 0 & 0 & 0 & 0 & 0 \\ 0 & 0 & 1 & 0 & 0 & 0 & 0 & 1 \\ 0 & 0 & 0 & 1 & 0 & 0 & 0 & 1 \\ 0 & 0 & 0 & 0 & 1 & 0 & 0 & 0 \\ 0 & 0 & 0 & 0 & 0 & 1 & 0 & 0 \\ 0 & 0 & 0 & 0 & 0 & 0 & 1 & 1\end{matrix} ] , \\ X ( i ) = [ \begin{matrix}{x}_{0} ( i ) \\ {x}_{1} ( i ) \\ {x}_{2} ( i ) \\ {x}_{3} ( i ) \\ {x}_{4} ( i ) \\ {x}_{5} ( i ) \\ {x}_{6} ( i ) \\ {x}_{7} ( i )\end{matrix} ] , \\ V = [ \begin{matrix}1 \\ 1 \\ 0 \\ 1 \\ 1 \\ 0 \\ 0 \\ 1\end{matrix} ] .$$

With reference still to FIG. 2, the following operations are performed in the CRC generator 10:
1. A switch 11 is in its upper position, at which it is configured to pass the output from the XOR gate 13.
2. The input data d(i) is fed into the CRC generator to and calculations according to (Equation 2) is performed cycle by cycle.
3. After feeding in all the bits of the input data d(i), the switch 11 is configured to input zero (reference numeral 14).
4. The result 12 is extracted by feeding zero 14 cycle by cycle.

If a message (reference numeral 2 of FIG. 1) is fed as the input data d(i), the generated CRC is obtained as the result 12. This operation corresponds to the arrow A1 of FIG. 1, which is CRC generation using Method F.

If the codeword (reference numeral 1 of FIG. 1) is fed as input data d(i), a null vector is obtained as the result 12 and the CRC check can be performed by verifying this. This operation corresponds to arrow A2 of FIG. 1, which is CRC checking using Method F.

If the codeword (reference numeral 1 of FIG. 1) in the reverse order is fed as input data d(i) and V and m are determined from the reverse generator polynomial, then the null vector is obtained as the result 12 and the CRC check may be performed to verify this. This operation corresponds to Arrow B2 in FIG. 1, which is Method R-0.

### Solving the Recurrence Equation

Generally, a recurrence equation is an equation that recursively defines a sequence once one or more initial terms are given. That is, each further term of the sequence is defined as a function of the preceding terms.

The recurrence equation (Equation 2) represents the model of the state transition from clock cycle #i to clock cycle #i+1. This recurrence equation needs to be solved in order to obtain the equivalent model to generate the CRC result X(n), where n is the length of the input data.

FIG. 3 illustrates how the recurrence equation (Equation 2) can be solved. In particular, the following operations are performed:
1. The first line in FIG. 3 is obtained by substituting i=j−1 to (Equation 2) and then renaming j to i.
2. The (n+1)-th line is obtained by substituting i=j−1 to the n-th line and multiplying M onto both sides, then renaming j to i, where 1≦n≦i−1.
3. Summing up from the first line to the i-th line. The term MⁿX(i) at the right-hand side of the n-th line is equal to the term MⁿX(i) at the left-hand side of the (n+1)-th line, and can be eliminated.

The result can be expressed as:

$$\begin{matrix}( Equation 3 ) & \\ X ( i ) = {M}^{i} X ( 0 ) + {\sum }_{j = 0}^{i - 1} {M}^{i - 1 - j} d ( j ) V & ( modulo 2 )\end{matrix}$$

It can be observed that:

X(0) is a null vector since the registers in the CRC generator are zero at the initial state. The final state X(n) represents the result which can be CRC or zero depending on the input data, message 2 (refer to FIG. 1) or codeword 1 (refer to FIG. 1). Thus CRC can be computed by feeding the message 2 as

$$\begin{matrix}( Equation 4 ) & \\ P = {\sum }_{j = 0}^{n - 1} {M}^{n - 1 - j} d ( j ) V & ( modulo 2 )\end{matrix}$$

where:
P: is a vector representing the CRC for the target input data block.

### Processing Multiple Input Bits in Parallel for Forward Order (Method F)

Consider processing of w bits in parallel. That is, bits #wi to #wi+w−1 are processed at clock cycle #i. The following is obtained from (Equation 3).

$$\begin{matrix}( Equation F ) & \\ \begin{matrix}X ( w ( i + 1 ) ) = {\sum }_{j = 0}^{w ( i + 1 ) - 1} {M}^{w ( i + 1 ) - 1 - j} d ( j ) V & ( modulo 2 ) \\ = {\sum }_{j = 0}^{wi - 1} {M}^{w ( i + 1 ) - 1 - j} d ( j ) V + & ( modulo 2 ) \\ {\sum }_{j = wi}^{w ( i + 1 ) - 1} {M}^{w ( i + 1 ) - 1 - j} d ( j ) V & \\ = {M}^{w} {\sum }_{j = 0}^{wi - 1} {M}^{wi - 1 - j} d ( j ) V + & ( modulo 2 ) \\ {\sum }_{j = 0}^{w - 1} {M}^{w - 1 - j} d ( j + wi ) V & \\ = {M}^{w} X ( wi ) + {\sum }_{j = 0}^{w - 1} {M}^{w - 1 - j} d ( j + wi ) V & ( modulo 2 )\end{matrix} & \end{matrix}$$

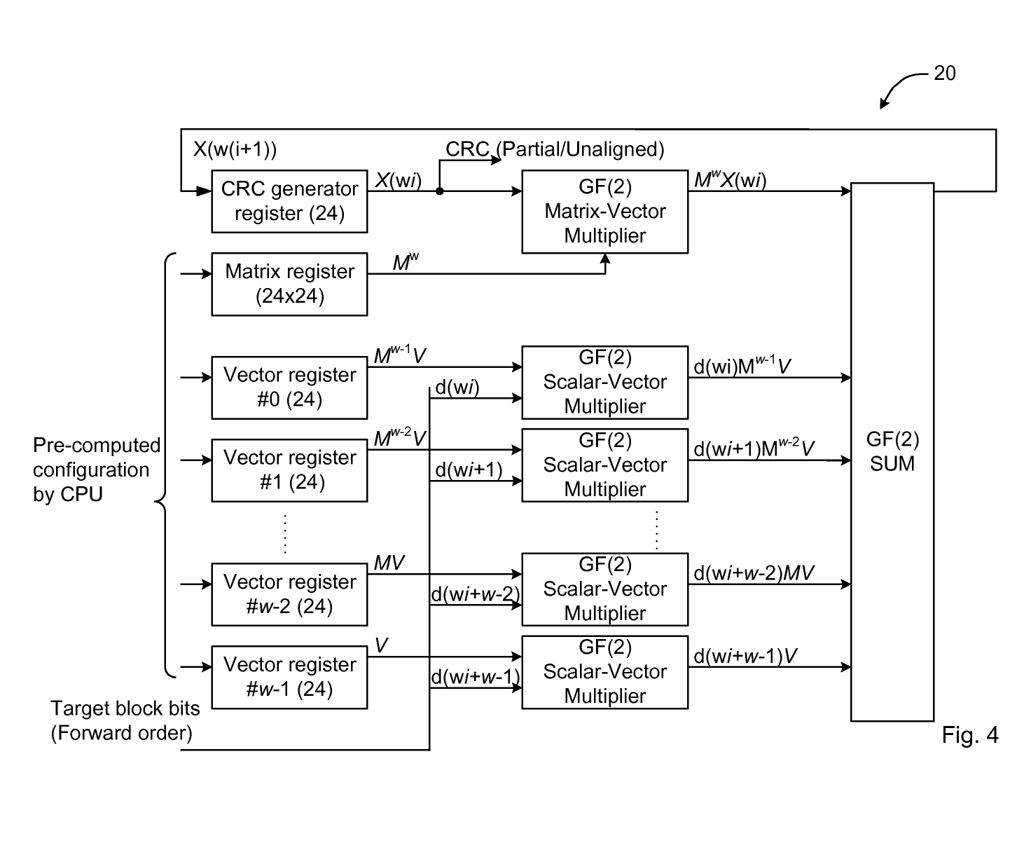

FIG. 4 illustrates an exemplary CRC generator core 20 supporting forward order calculation (Method-F). From the above description of processing multiple input bits in parallel, a multiple-input bits CRC generator core may be constructed. The CRC generator core 20 is implemented to perform the calculation in (Equation F). The CRC generator core 20 may for instance, as illustrated in FIG. 4, comprise a CRC generator register receiving the next state as input X(w(i+1)) and outputting X(wi) as the current state, where the final state is output as partial/unaligned CRC; a matrix register receiving as input pre-computed configuration from CPU and outputting M^{w}; vector registers receiving as input pre-computed configuration from CPU and outputting M^{w-1-j}V for all j from 0 to w−1 in parallel; matrix-vector multiplier receiving as input the output X(wi) from the CRC generator register and outputting, to an adder, M^{w}X(wi); scalar-vector multipliers receiving as input the output M^{w-1-j}V from a respective one of the vector registers and target block bits d(wi+j) for all j from 0 to w−1 in parallel in forward order and outputting the multiplication of the input, i.e. d(wi+j) M^{w-1-j}V; and an adder receiving the output from the scalar-vector multipliers. This CRC generator supports any CRC up to 24-bits for forward order calculation.

### Processing Multiple Input Bits in Parallel for Reverse Order CRC Check (Method R-0)

If the codeword 1 in the reverse order is fed as input data d(i), and further V and M are determined from the reverse generator polynomial, the null vector is obtained by (Equation F) and the CRC check can be performed by verifying this, where multiple input bits are processed in parallel.

Principle of Parallel Calculation with Multi-Core Engines for Forward Order (Method F)

In the following, splitting the block of length n=l+m into sub block #0 of length l and sub block #1 of length m is considered.

The CRC for the original input data block is calculated as:

$$\begin{matrix}( Equation 23 ) & \\ P = {\sum }_{j = 0}^{l + m - 1} d ( j ) {M}^{l + m - 1 - j} V & ( modulo 2 )\end{matrix}$$

The calculation for sub blocks is split according to:

$$\begin{matrix}( Equation 24 ) \\ \begin{matrix}P = {\sum }_{j = 0}^{l - 1} d ( j ) {M}^{l + m - 1 - j} V + {\sum }_{j = l}^{l + m - 1} d ( j ) {M}^{l + m - 1 - j} V & ( modulo 2 ) \\ = {M}^{m} {\sum }_{j = 0}^{l - 1} d ( j ) {M}^{l - 1 - j} V + {\sum }_{j = 0}^{m - 1} d ( j + l ) {M}^{m - 1 - j} V & ( modulo 2 ) \\ = {M}^{m} {P}_{0} + {P}_{1} & ( modulo 2 )\end{matrix}\end{matrix}$$

where the following are defined:
Pk: The partial CRC vector which represents aligned CRC computed for the sub block #k.
and

$$\begin{matrix}( Equation 25 ) & \\ {P}_{0} = {\sum }_{j = 0}^{l - 1} d ( j ) {M}^{l - 1 - j} V & ( modulo 2 ) \\ ( Equation 26 ) & \\ {P}_{1} = {\sum }_{j = 0}^{m - 1} d ( l + j ) {M}^{m - 1 - j} V & ( modulo 2 )\end{matrix}$$

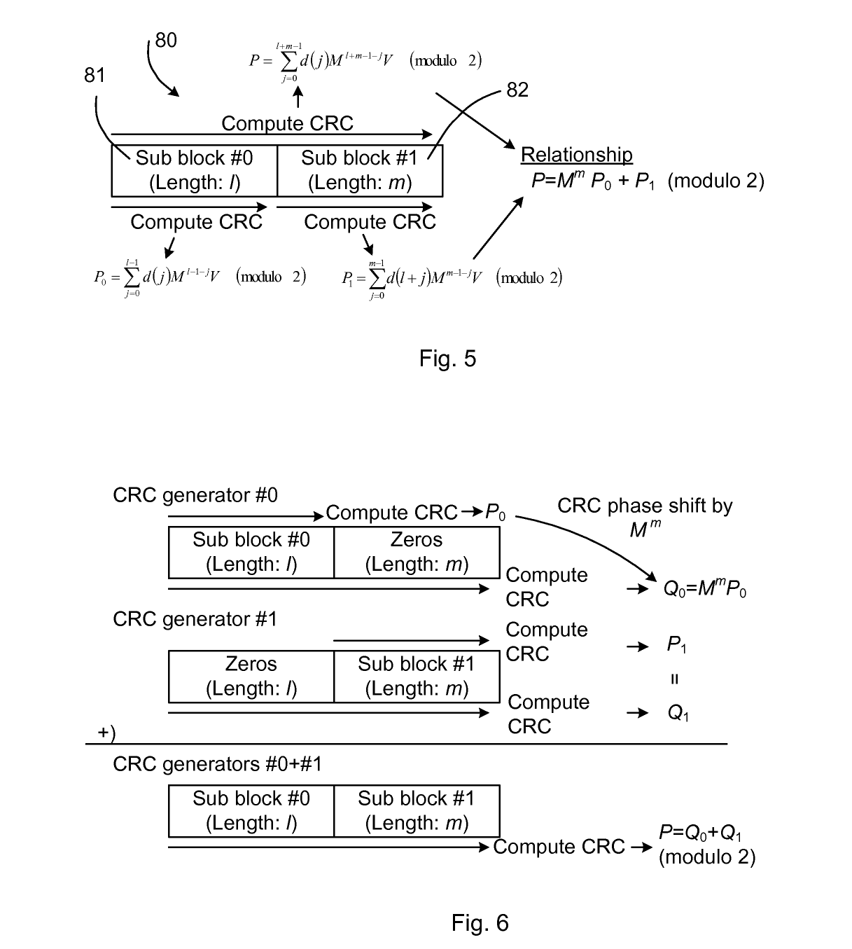

FIG. 5 illustrates the splitting of the calculation with forward order input. A CRC code is to be calculated for a message block 80 comprising a first sub-block of length l (reference numeral 81) and a second sub-block of length m (reference numeral 82).

A CRC code P for the message block 80 may be calculated for the entire block according to:

$$\begin{matrix}( Compare equation 23 ) & \\ P = {\sum }_{j = 0}^{l + m - 1} d ( j ) {M}^{l + m - 1 - j} V & ( modulo 2 )\end{matrix}$$

A first partial CRC code P₀ (also denoted segment CRC code in this disclosure) may be determined for the first sub-block 81 according to:

$$\begin{matrix}( Compare equation 25 ) & \\ {P}_{0} = {\sum }_{j = 0}^{l - 1} d ( j ) {M}^{l - 1 - j} V & ( modulo 2 )\end{matrix}$$

A second partial CRC code P₁ may be determined for the second sub-block 82 according to:

$$\begin{matrix}( Compare equation 26 ) & \\ {P}_{1} = {\sum }_{j = 0}^{m - 1} d ( l + j ) {M}^{m - 1 - j} V & ( modulo 2 )\end{matrix}$$

The relationship between the calculation of CRC code for the entire message block and the calculations of partial CRC codes for the sub-blocks can be expressed by:

P=M^{m}P₀+P₁(modulo 2)

From the above equation, it is seen that the first sub-block 81 is phase shifted by the multiplication with M^{m}, while the second sub-block 82 needs no phase shifting. Thus the CRC calculation can be split as described.

FIG. 6 is a graphical explanation of the above calculations (illustrated in FIG. 5), i.e. of the split of CRC calculation. Two CRC generators, a first CRC generator #0 and a second CRC generator #1 are provided, each arranged to calculate a partial CRC code. The first CRC generator #0 calculates the partial CRC code P₀ for the first sub-block 81, and phase shifts it by M^{m}, giving Q₀=M^{m}P⁰. The second CRC generator #1 calculates the partial CRC code P₁ for the second sub-block 82, for which no phase shift is needed, giving Q₁=P¹.

The above is equivalent to calculating CRC code for the entire message block, as has been described, giving P=Q₀+Q₁ (modulo 2).

Multiplying M^{m} onto the partial CRC code is equivalent to feeding m bits of zeros to the CRC generator and by this the phase shift of CRC is performed. It is noted that if the last partial sub-block (last segment) is calculated in forward order, then a phase shift for this segment is not needed. Therefore, more generally stated, the partial CRC codes are aligned rather than shifted, wherein bits are shifted if needed, and not shifted if already aligned.

Above, known methods have been described for providing thorough understanding of the present disclosure, i.e. forward order CRC check/generation with generator polynomial, reverse order CRC check with reverse generator polynomial, processing multiple bits in parallel for the forward order, parallel calculation with multi-core engines for the forward order, and processing multiple bits in parallel for the reverse order. Next, an aspect of the present disclosure is described.

### Computing CRC in the Reverse Order (Method R-1)

The above described method (Method R-0) can be used only for reverse order CRC check and not for CRC generation. In contrast, the following methods may be used for reverse order CRC check or generation. The reverse calculations of Method-F are taken advantage of.

The reverse operation of (Equation-2) (least significant bit input first) is expressed as

X(i)=M⁻¹(X(i+1)+d(i)V)(modulo 2) (Equation 5)

Reordering the expression above as Y(i)=X(n−i) and q(i)=d(n−1−i). It is noted that the first element for {X(i)} is X(0) and last element is X(n), while the first element for {d(i)} is d(0) and last element is d(n−1).

Then the following is obtained:

Y(i+1)=M⁻¹(Y(i)+q(i)V)(modulo 2) (Equation 6)

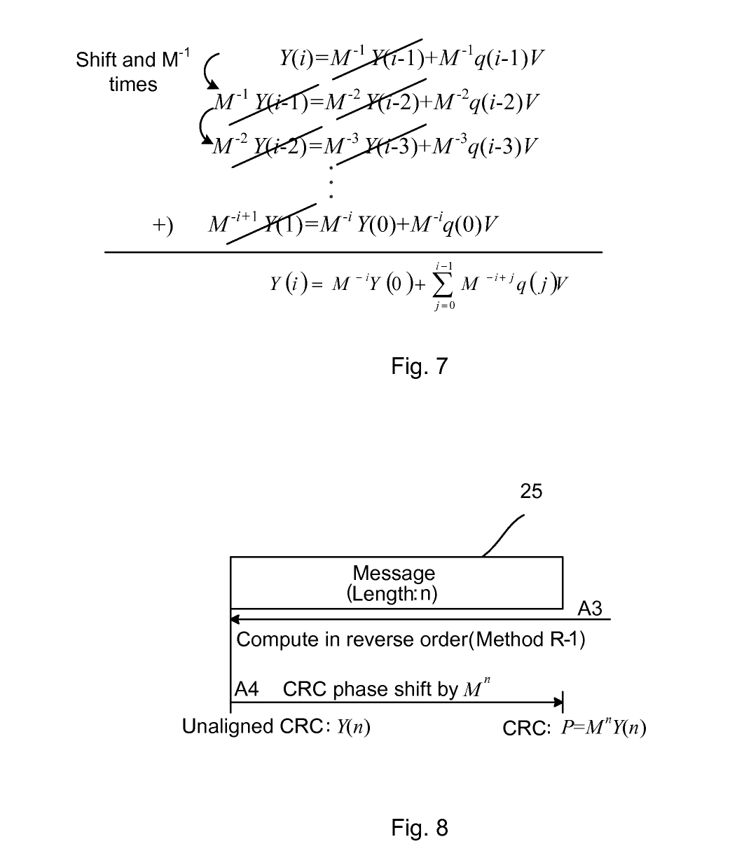

This recurrence equation (Equation 6) can be solved as shown in FIG. 7. In particular, the following operations are performed:
1. The first line of FIG. 7 is obtained by substituting i=j−1 to (Equation 6) then renaming j to i.
2. The (n+1)-th line is obtained by substituting i=j−1 to the n-th line and multiplying M⁻¹ onto both sides and then renaming j to i, where 1≦n≦i−1.
3. Summing up from the first line to the i-th line. The term M⁻ⁿY(i) at the right-hand side of the n-th line is equal to the term M⁻ⁿY(i) at the left-hand side of the (n+1)-th line, and can be eliminated.

The following is obtained:

$$Y ( i ) = {M}^{- i} Y ( 0 ) + {\sum }_{j = 0}^{i - 1} {M}^{- i + j} q ( j ) V ( modulo 2 ) \qquad ( Equation 7 )$$

It can be assumed that Y (0) is null vector, then

$$Y ( n ) = {\sum }_{j = 0}^{n - 1} {( {M}^{- 1} )}^{n - j} q ( j ) V ( modulo 2 ) \qquad ( Equation 8 )$$

(Equation 4) can be rearranged as follows:

$$P = {M}^{n} {\sum }_{j = 0}^{n - 1} {( {M}^{- 1} )}^{n - j} q ( j ) V ( modulo 2 ) \qquad ( Equation 9 )$$

From (Equation 8) and (Equation 9), the CRC result is:

P=MⁿY(n)(modulo 2) (Equation 10)

The computation in the reverser order by (Equation-8) generates Y(n) which is denoted unaligned CRC. The alignment of the CRC is corrected, i.e. alignment of CRC is obtained, by multiplying the unaligned CRC, i.e. Y(n) with the matrix Mⁿ (CRC phase shift). FIG. 8 illustrates this alignment correction in the reverse order calculation. In particular, a target block for which CRC is to be computed is indicated at reference numeral 25, as a message of length n. For computing this CRC, Method R-1, as described, is used (arrow A3). Then (arrow A4) CRC phase shift is performed by multiplying the CRC with the matrix Mⁿ. The aligned CRC P is then obtained from the unaligned CRC Y(n) by above Equation 10.

### Inverse of Matrix and Related Property

Defining a vector U with length L−1 which vector U is created from V by excluding the first element according to:

$$V = [ \begin{matrix}1 \\ U\end{matrix} ]$$

Then the matrix M can be expressed as

$$M = [ \begin{matrix}{O}_{1 , L - 1} & 1 \\ {I}_{L - 1} & U\end{matrix} ] ,$$

where Iₙ is n by n identity matrix and O_{m,n} is m by n null matrix.

The inverse of matrix Min GF(2) can then be obtained as

$${M}^{- 1} = [ \begin{matrix}U & {I}_{L - 1} \\ 1 & {O}_{1 , L - 1}\end{matrix} ] \qquad ( Equation 11 )$$

This can be proved by the multiplication results I_{L}:

$$\begin{matrix}[ \begin{matrix}{O}_{1 , L - 1} & 1 \\ {I}_{L - 1} & U\end{matrix} ] [ \begin{matrix}U & {I}_{L - 1} \\ 1 & {O}_{1 , L - 1}\end{matrix} ] = [ \begin{matrix}{O}_{1 , L - 1} \cdot U + 1 \cdot 1 & {O}_{1 , L - 1} \cdot {I}_{L - 1} + 1 \cdot {O}_{1 , L - 1} \\ {I}_{L - 1} \cdot U + U \cdot 1 & {I}_{L - 1} \cdot {I}_{L - 1} + U \cdot {O}_{1 , L - 1}\end{matrix} ] \\ = [ \begin{matrix}1 & {O}_{1 , L - 1} \\ U + U & {I}_{L - 1}\end{matrix} ] \\ = {I}_{L} ( ∵ U + U = {O}_{L - 1 , 1} in GF ( 2 ) )\end{matrix}$$

The following property is also true:

$$\begin{matrix}{M}^{- 1} V = [ \begin{matrix}U & {I}_{L - 1} \\ 1 & {O}_{1 , L - 1}\end{matrix} ] [ \begin{matrix}1 \\ U\end{matrix} ] \\ = [ \begin{matrix}1 \cdot U + {I}_{L - 1} \cdot U \\ 1 \cdot 1 + {O}_{1 , L - 1} \cdot U\end{matrix} ] \\ = [ \begin{matrix}U + U \\ 1\end{matrix} ] \\ = [ \begin{matrix}{O}_{L - 1 , 1} \\ 1\end{matrix} ] ( ∵ U + U = {O}_{L - 1 , 1} in GF ( 2 ) )\end{matrix} \qquad ( Equation 12 )$$

### Implementation of CRC Generator in Reverse Order (Method R-1)

(Equation 6) can be simplified according the following by using (Equation 12):

$$Y ( i + 1 ) = {M}^{- 1} Y ( i ) + q ( i ) [ \begin{matrix}{O}_{L - 1 , 1} \\ 1\end{matrix} ] ( modulo 2 ) \qquad ( Equation 13 )$$

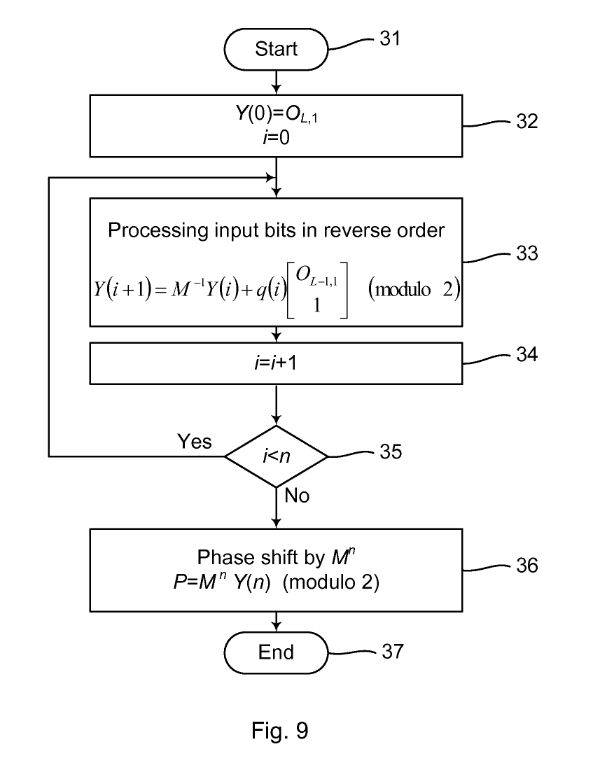

FIG. 9 is a flow chart 30 for CRC generation with reverse order input block using Method R-1. The calculation can be performed according to the Equation 13. The result is then shifted by multiplying the matrix as in (Equation 10). A bit more elaborated: the flow starts at box 31 and in box 32, Y(0) is set equal to O_{L,1}, i=0. In box 33, input bits are processed in reverse order according to (Equation 13) as above. In box 34, i is set equal to i+1 and in box 35 it is checked if i is less than n. If yes, i.e. if i<n then flow reverts to box 33 and processing of box 33 and counter increase of box 34 is performed again. If, in box 35, i is not smaller than n, then flow continues to box 36, wherein the phase shift is performed by multiplying the matrix Mⁿ, i.e. (Equation 10).

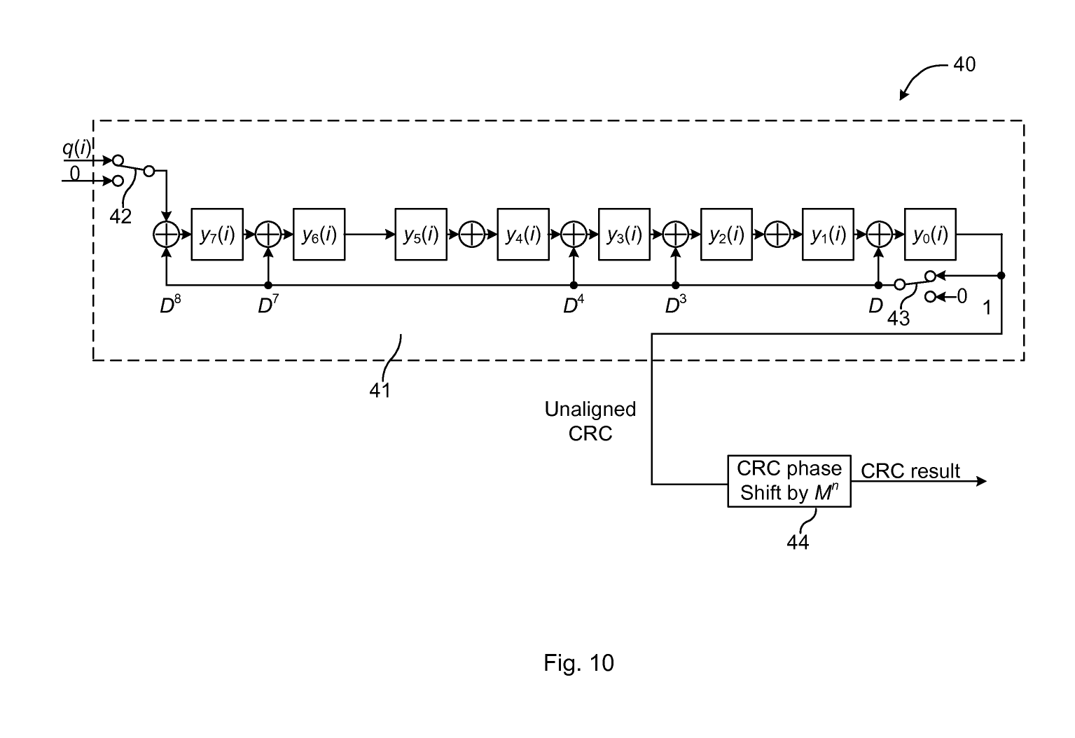

FIG. 10 illustrates an example of a hardware implementation of Method R-1 for CRC8 generator. The CRC8 generator 40 comprises an unaligned CRC generator 41, a switch 42 to select the input, a switch 43 to select the feedback, and CRC phase shifters 44.
1. The switch 42 is configured to pass the input message in the reverse order q(i) and the switch 43 is configured to pass the feedback.
2. The message in the reverse order q(i) is fed to the unaligned CRC generator 41 cycle by cycle.
3. After feeding all bits in the message q(i), the switches 42 and 43 are configured to input zeros.
4. The result of the unaligned CRC generator 41 is extracted by feeding zeros and is then sent to the CRC phase shifter 44.
5. The aligning of CRC is performed by multiplying the matrix Mⁿ in the CRC phase shifter 44 and CRC result is obtained.

### Shifting Register State in the Reverse Order CRC Calculation (Method R-2)

In the following, the shift of register state is considered in preparation of making a unified formula with forward CRC calculation.

Define \hat{Y}(i)=MY(i)(modulo 2) (Equation 14)

Applying (Equation 14) in (Equation 6), (Equation 7), (Equation 8) and (Equation 10), then these formulas are modified as

$$\begin{matrix}\hat{Y} ( i + 1 ) = \hat{Y} ( i ) + q ( i ) V ( modulo 2 ) & ( Equation 15 ) \\ \hat{Y} ( i ) = {M}^{- i} \hat{Y} ( 0 ) + {\sum }_{j = 0}^{i - 1} {( {M}^{- 1} )}^{i - 1 - j} q ( j ) V ( modulo 2 ) & ( Equation 16 ) \\ \hat{Y} ( n ) = {\sum }_{j = 0}^{n - 1} {( {M}^{- 1} )}^{n - 1 - j} q ( j ) V ( modulo 2 ) & ( Equation 17 ) \\ P = {M}^{n - 1} \hat{Y} ( n ) ( modulo 2 ) & ( Equation 18 )\end{matrix}$$

Here it is noticed that the CRC phase shift is performed by multiplying the unaligned CRC with Mⁿ⁻¹ and not with Mⁿ as in method R-1.

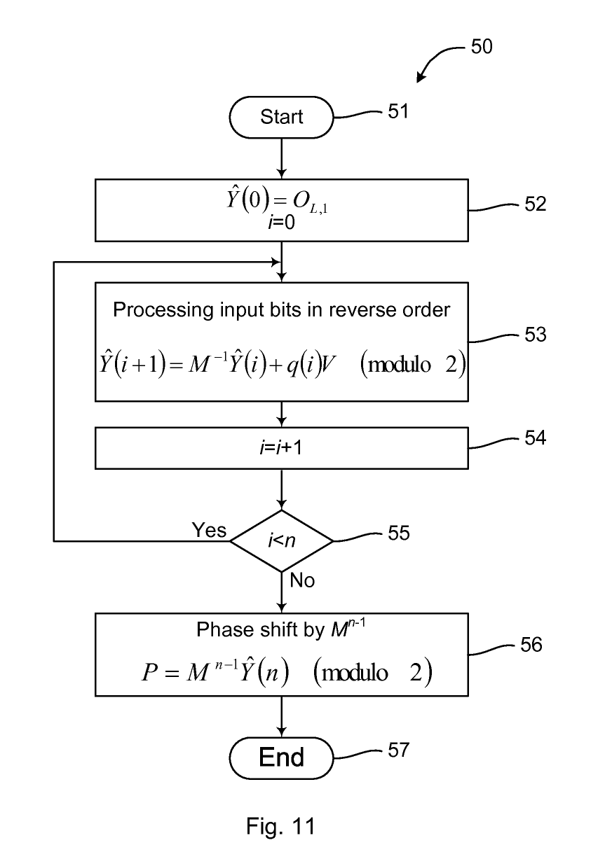

FIG. 11 is a flow chart for CRC generation with reverse order input block using Method R-2. The method 50 for CRC generation with reverse order input starts at box 51, from which flow continues to box 52. In box 52, Ŷ(0) is set equal to null matrix O_{L,1} of size L by 1.

In box 53 the input bits are processed in reverse order according to

\hat{Y}(i+1)=M⁻¹Y(i)+q(i)V(modulo 2)

In box 54 i is increased by 1, i.e. i is set equal to i+1. Flow then continues to decision box 55, wherein it is determined whether i is smaller than n, if yes then flow reverts to box 53 and the actions of boxes 53, 54 and 55 are repeated. If, in box 55, it is determined that i is not smaller than n, i.e. it is determined that i is larger than n, then flow continues to box 56.

In box 56 a phase shift by Mⁿ⁻¹ is performed according to

P=Mⁿ⁻¹Ŷ(n)(modulo 2).

The method 50 results in a CRC code generated for an reverse input order of bits and the flow ends at box 57.

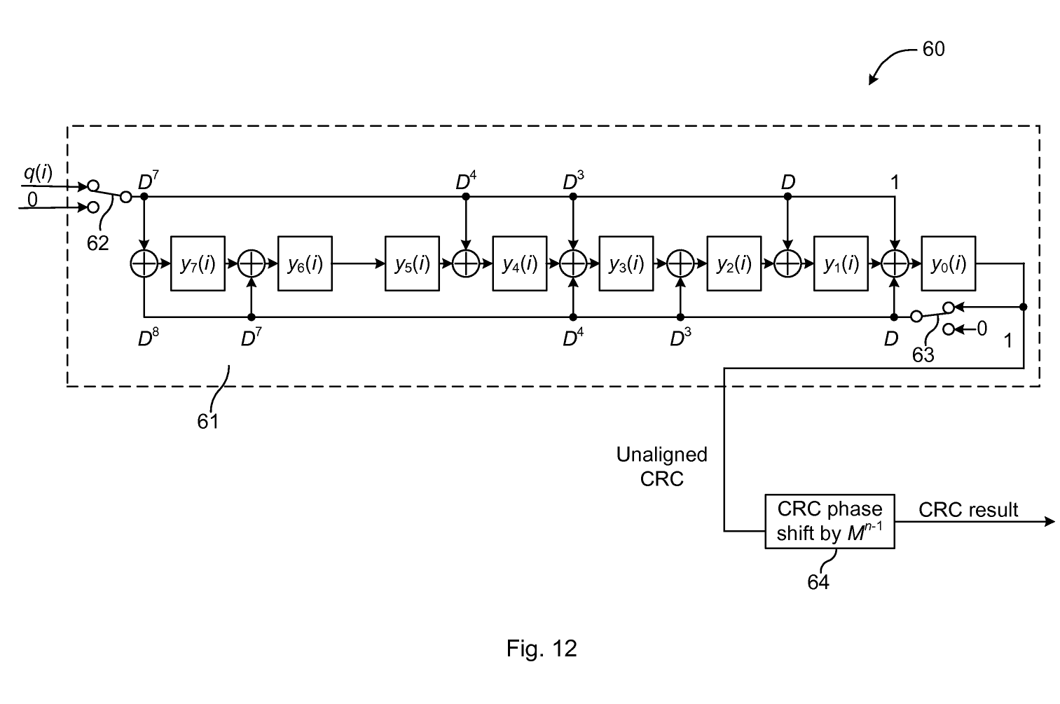

FIG. 12 illustrates an example of a hardware implementation of Method R-2 for CRC8 generator. The CRC8 generator 60 comprises of an unaligned CRC generator 61, a switch 62 to select the input, a switch 63 to select the feedback, and CRC phase shifters 64.
1. The switch 62 is configured to pass the input message in the reverse order q(i) and the switch 63 is configured to pass the feedback.
2. The message in the reverse order q(i) is fed to the unaligned CRC generator 61 cycle by cycle.
3. After feeding all bits in the message q(i), the swatches 62 and 63 are configured to input zeros.
4. The result in the unaligned CRC generator 61 is extracted by feeding zeros and it is send to the CRC phase shifter 64.

The aligning of CRC is performed by multiplying the matrix Mⁿ in the CRC phase shifter 64 and CRC result is obtained.

### Generic Formula for Forward Order Mode and Reverse Order Mode (Method M)

The formula for the CRC calculations in forward (conventional) order and reverse order can be unified. Defining Z(i), r(i) and H according to:

$$[ \begin{matrix}Z ( i ) & r ( i ) & H & S\end{matrix} ] = \{ \begin{matrix}[ \begin{matrix}X ( i ) & d ( i ) & M & {I}_{L , L}\end{matrix} ] & ( forward order mode ) \\ [ \begin{matrix}\hat{Y} ( i ) & q ( i ) & {M}^{- 1} & {M}^{n - 1}\end{matrix} ] & ( reverse order mode )\end{matrix}$$

Assuming Z(0)=O_{L,1} and applying (Equation 3), (Equation 7) and (Equation 16) gives:

$$\begin{matrix}Z ( i ) = {\sum }_{j = 0}^{i - 1} {H}^{i - 1 - j} r ( j ) V ( modulo 2 ) & ( Equation 20 ) \\ P = SZ ( n ) ( modulo 2 ) & ( Equation 21 )\end{matrix}$$

### Processing Multiple Input Bits in Parallel (Method M)

Consider processing of w bits in parallel. That is, bits #wi to #wi+w−1 are processed at clock cycle #i.

(Equation F) for the forward order calculation can be generalized for applying to a segment where the data is fed in either forward or reverse order. This is performed by renaming X to Z, M to H and d to r in (Equation F) as:

$$\begin{matrix}Z ( w ( i + 1 ) ) = {\sum }_{j = 0}^{w ( i + 1 ) - 1} {H}^{w ( i + 1 ) - 1 - j} r ( j ) V ( modulo 2 ) \\ = {H}^{w} Z ( wi ) + {\sum }_{j = 0}^{w - 1} {H}^{w - 1 - j} r ( j + wi ) V ( modulo 2 )\end{matrix} \qquad ( Equation 22 )$$

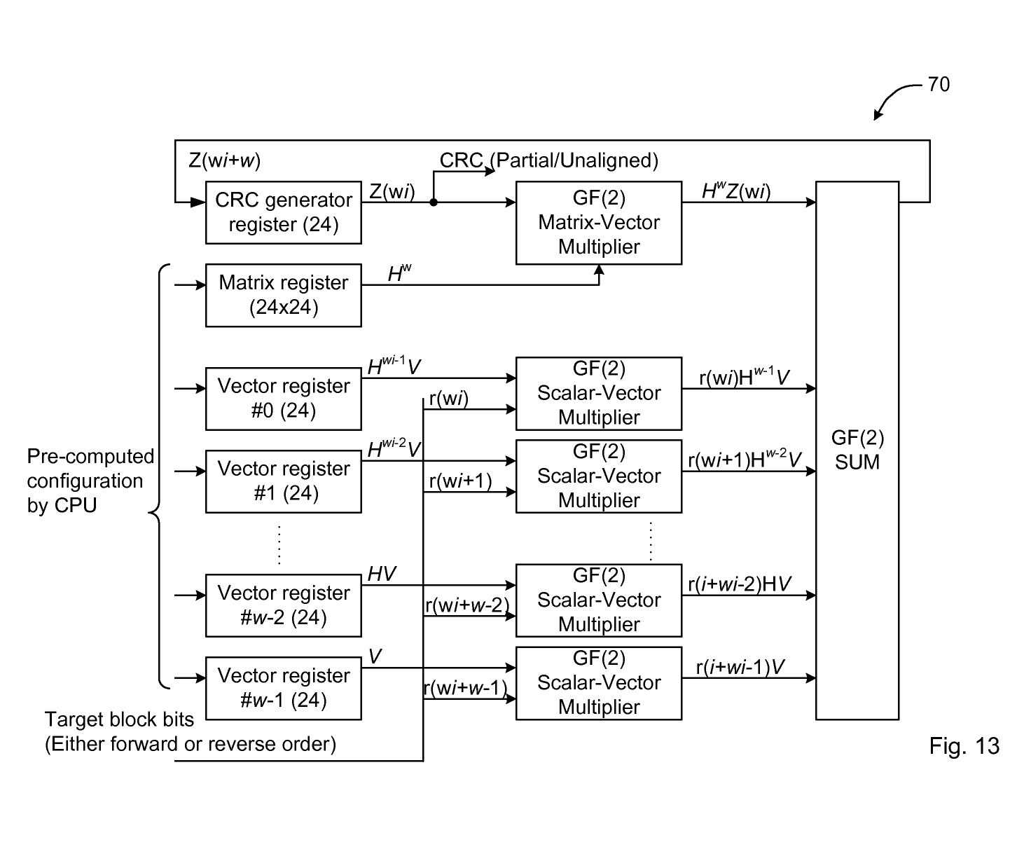

FIG. 13 illustrates an exemplary CRC generator core 70 supporting both forward and reverse modes (Method-M). From the above description of processing multiple input bits in parallel, a multiple-input bits CRC generator core may be constructed. The CRC generator core is implemented to perform the calculation in (Equation 22). This CRC generator supports any CRC up to 24-bits and both forward and reverse orders are supported. The selection of forward or reverser order mode is performed by the choice of the pre-computed matrix. In the case of reverse order mode, the obtained CRC is unaligned.

The CRC generator core 70 may for instance, as illustrated in FIG. 13, comprise a CRC generator register receiving the next state as input Z(wi+w) and outputting Z(wi) as the current state, where the final output is output as partial/unaligned CRC; a matrix register receiving as input pre-computed configuration from CPU and outputting H^{w}; vector registers receiving as input pre-computed configuration from CPU and outputting H^{w-1-j}V for all j from 0 to w−1 in parallel; matrix-vector multiplier receiving as input the output Z(wi) from the CRC generator register and outputting, to an adder, H^{w}Z(wi); scalar-vector multipliers receiving as input the output H^{w-1-j}V from a respective one of the vector registers and target block bits r(wi+j) for all j from 0 to w−1 in parallel in forward order or reverse order and outputting the multiplication of the input, i.e. r(wi+j) H^{w-1-j}V; and an adder receiving the output from the scalar-vector multipliers.

Parallel Calculation with Multi-Core Engines

The method for splitting the CRC calculation by (Equation 24) can be also applied for the calculation with reverse order or mixed order, and the calculation of P₀ and P₁ can be performed in a reverse order. In the reverse order calculation, the unaligned CRC is obtained and the phase needs to be shifted by multiplying the matrix. The matrix multiplication for the reverse order calculation (Equation 18) and combining the CRCs (Equation 24) can be merged. When the calculation is split into more than two sub blocks, this split of the calculation may be recursively applied.

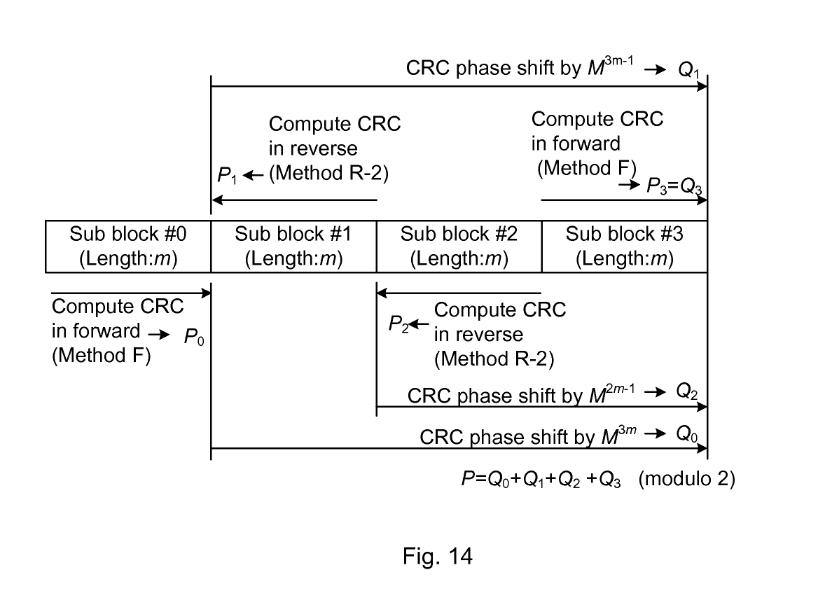

FIG. 14 illustrates an example for combining four sub-blocks with mixture of forward and reverse order calculations. The total value of the phase shift for splitting the CRC calculation and reverse calculation is considered. A first sub-block #0, a second sub-block #1, a third sub-block #2 and a fourth sub-block #3 is thus illustrated in FIG. 14.

For the first sub-block #0 a partial CRC code (herein also denoted segment CRC code) is calculated in forward order (Method F), giving P₀, which is then phase shifted by multiplying with M^{3m} giving Q₀.

For the second sub-block #1 a partial CRC code is calculated in reverse order (Method R-2), giving P₁, which is then phase shifted by multiplying with M^{3m-1} giving Q₁.

For the third sub-block #2 a partial CRC code is, as the second sub-block #1, calculated in reverse order (Method R-2), giving P₂, which is then phase shifted by multiplying with M^{2m-1} giving Q₂.

Finally, for the fourth sub-block #3 a partial CRC code is calculated in forward order (Method F), giving P₃, which does not to be phase shifted (being the last partial CRC code) and thus P₃=Q₃.

The partial CRC codes are then added giving P=Q₀+Q₁+Q₂+Q₃ (modulo 2).

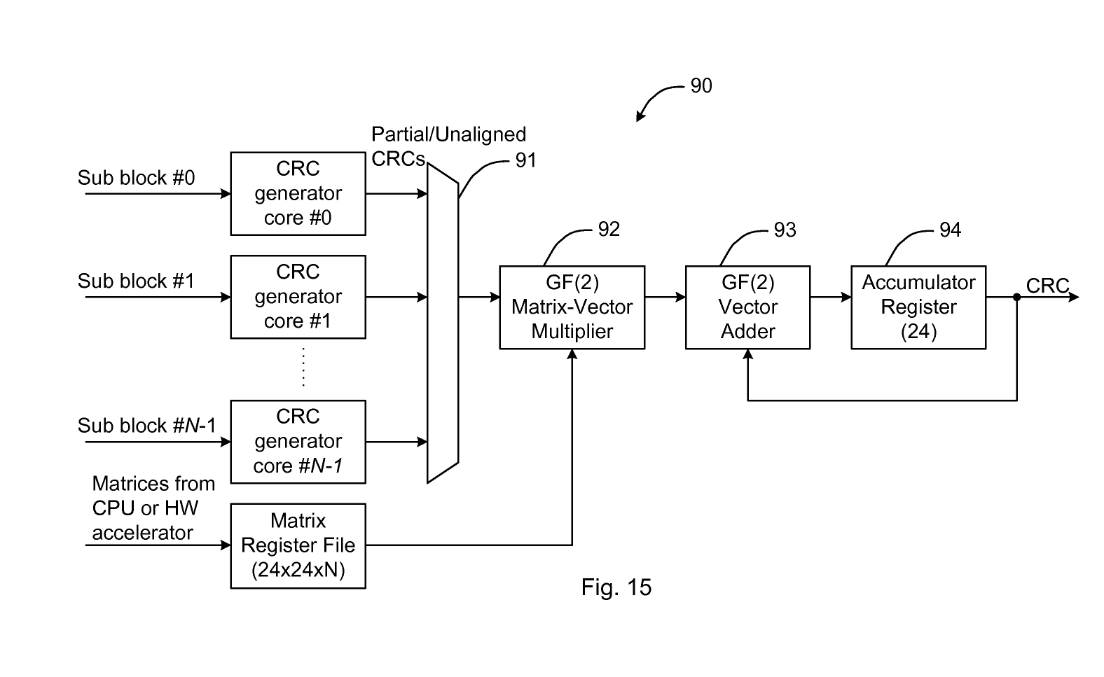

FIG. 15 illustrates an example of a hardware implementation to combine the partial CRCs computed by each CRC core with phase shift. In this device 90, a sub block is processed by a respective CRC engine core (CRC generator cores #0, #1, . . . , #N−1), which results in an unaligned/partial CRC, indicated at reference numeral 91. Then the unaligned/partial CRCs phase shifted by multiplying matrices, e.g. in a GF(2) matrix-vector multiplier as indicated at reference numeral 92, after which unaligned/partial CRCs are combined, e.g. in a GF(2) vector adder as indicated at reference numeral 93. An accumulator register 94 may also be included for storing intermediate arithmetic and logic results. The output of device 90 is then the total CRC code. The matrices for the phase shifts can be pre-computed by a central processing unit (CPU) and/or hardware accelerator(s).

### Computing a Power of Matrix

A power of matrix (Mⁿ) is preferably prepared by a CPU or hardware accelerator for each sub-block, because M and n depend on the data format and can be specified before receiving the data.

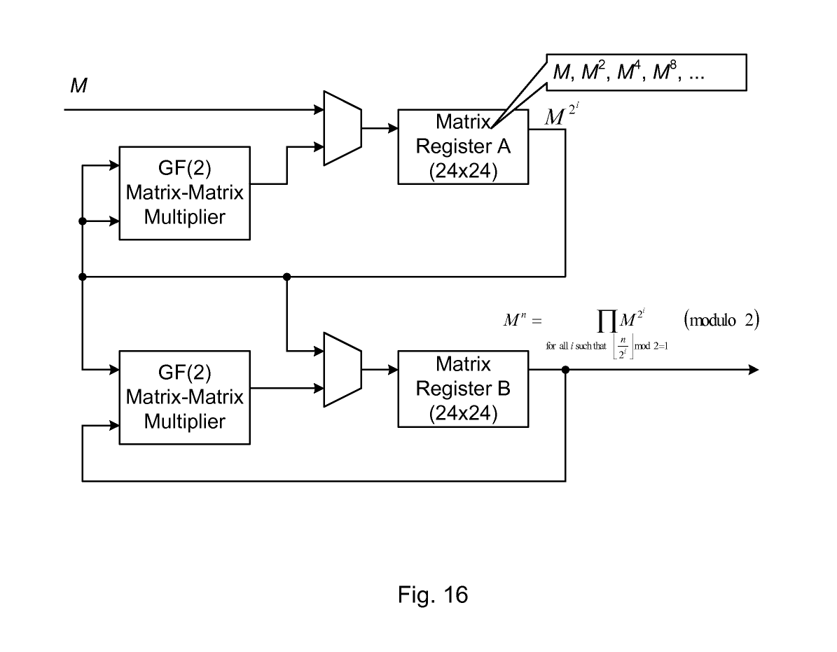

FIG. 16 illustrates an example of the hardware accelerator for computing Mⁿ. At step #i, M²^{ⁱ} is generated in matrix register A. Then

$${M}^{n} = {\prod }_{for all i such that ⌊ \frac{n}{{2}^{i}} ⌋ mo d 2 = 1} {M}^{{2}^{i}} ( modulo 2 )$$

is computed with matrix register B where the condition

$$⌊ \frac{n}{{2}^{i}} ⌋ mod 2 = 1$$

means the bit #i of the binary representation of n is equal to 1. The calculation of Mⁿ will be finished in └log₂ n┘+2 cycles. As a particular example, a GF(2) Matrix-Matrix multiplier which supports up to the size of a 24×24 matrix can be built with 13824 AND gates and 13248 XOR gates. The above provides an exemplary hardware accelerator and it is noted that other designs are conceivable.

### Comparison of State Transition for Various CRC Calculation Methods

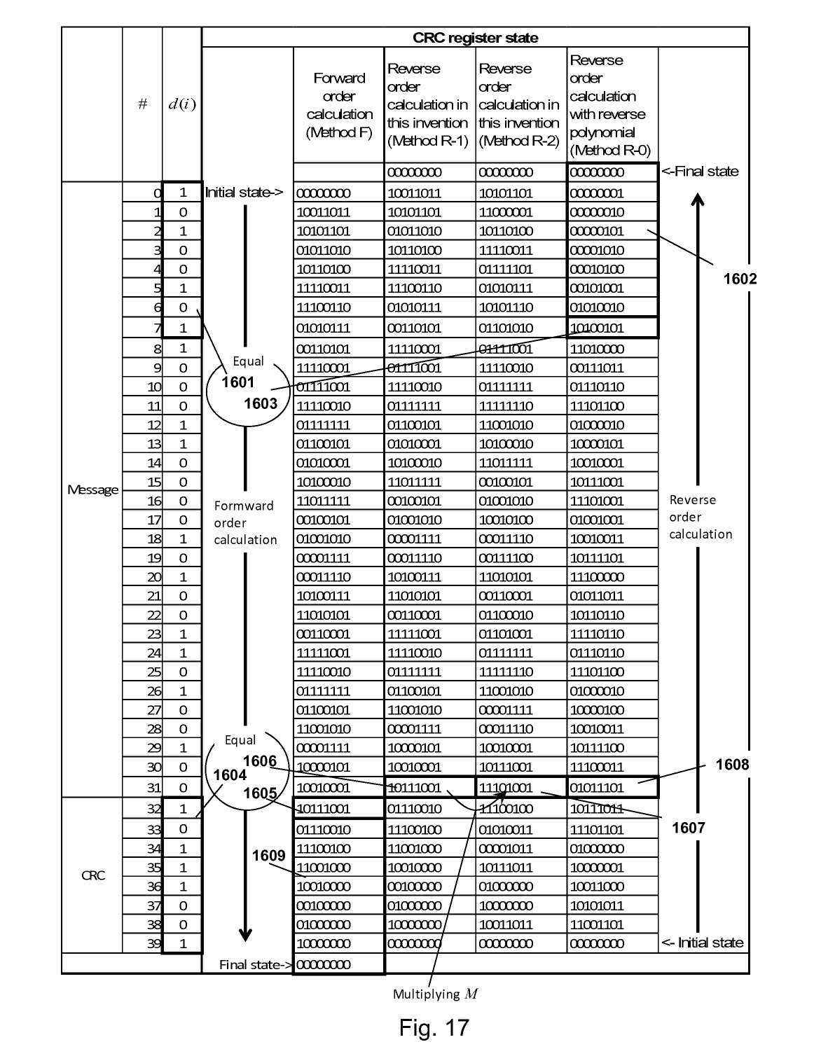

FIG. 17 illustrates state transitions of CRC registers. There is an interesting observation when the state transition of CRC register according to aspects of the present disclosure is compared with the method with reverse polynomial. In this comparison, 32-bits of message and 8 bit of CRC are feed for the CRC check is performed. In all three calculations, CRC register starts with zero and ends with zero.

Method F (a Known Art): Forward Order CRC Check or Generation with Polynomial:

G_{CRC 8}(D)=D⁸+D⁷+D⁴+D³+D+1

CRC register state after feeding all message bits (see reference numeral 1605) is equivalent to CRC (see reference numeral 1604), and then CRC register state proceeds as if the register data is shifted out (see reference numeral 1609).

Method R-1 (Provided by the Present Disclosure): Reverse Order CRC Check or Generation Method with Pure Reverse Calculation of Method F.

The transition of CRC register state is completely equivalent to the reverse of Method F. For example (1606) is equal to (see reference numeral 1605).

Method R-2 (Provided by the Present Disclosure): Reverse Order CRC Check or Generation Method where the Internal State is Modified from Method R-1.

The CRC register state is equivalent to the CRC register state for method R-1 multiplied by M. For example (see reference numeral 1607) is obtained by multiplying M to (see reference numeral 1606).

Method R-0 (a Known Art): Reverse Order CRC Check Method with Reverse Polynomial:

G_{CRC 8}^{R}(D)=D⁸+D⁷+D⁵+D⁴+D+1

The CRC register state after feeding CRC (see reference numeral 1608) is far different from (see reference numeral 1604) because CRC is convolved. CRC register state after feeding codeword excluding first 8 bits of message (see reference numeral 1603) is equivalent to the first 8 bits of message (see reference numeral 1601), and then CRC register state proceeds as if the register data is shifted out (see reference numeral 1602).

According to this observation, it can be seen that the CRC register state is rewound by Method R-1 or R-2 as the reverse operation of Method F, while another type of calculation is performed by Method R-0.

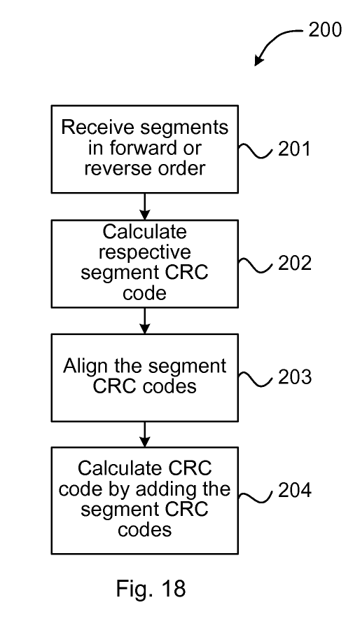

FIG. 18 illustrates a flow chart over steps of a method 200 in a CRC generator in accordance with the present disclosure. The features that have been described can be combined in different ways, examples of which are given in the following.

A method 200 is provided that may be performed in a cyclic redundancy check, CRC, device 300 for calculating, based on a generator polynomial G(x), a CRC code for a message block.

The method 200 comprises receiving 201 n segments of the message block in forward order or in reverse order, wherein at least one segment is received in reverse order.

The method 200 comprises calculating 202 for each of the n segments a respective segment CRC code based on the generator polynomial G(x), wherein each segment CRC is calculated according to the received order of the segment. The calculating in forward order comprises using a forward order generator polynomial G(x) and the calculating in reverse order comprises using the reverse order of the generator polynomial G(x). In the present description, “segment CRC code” and “partial CRC code” are used in an interchangeable manner, both intended to refer to a CRC code for a partial message block based on a generator polynomial.

The method 200 comprises aligning 203 each of the n segment CRC codes. It is noted that “aligning” may by need not entail phase shifting (as also mentioned earlier, e.g. with reference to FIG. 6).

The method 200 comprises calculating 204 the CRC code for the message block by adding together each of the aligned n segment CRC codes.

In an embodiment, the receiving 201 comprises receiving n segments of the message block in forward order or in reverse order, wherein n is equal to or larger than 2 and wherein at least one segment is received in forward order and at least one segment is received in reverse order.

In an embodiment, the calculating 202 for each of the n segments a respective segment CRC code, comprises processing input bits of a segment in forward order or reverse order by obtaining a respective pre-computed matrix.

In an embodiment, the aligning 203 of each of the segment CRC code comprises:
obtaining, from a CRC register, a respective power of a matrix M, the matrix M comprising an L by L constant matrix related to the generator polynomial G(x), wherein L is the length of the CRC code, and
multiplying the respective power of the matrix M with the respective segment CRC code.

In an embodiment, the method 200, comprises calculating 202 and aligning 203 in parallel the n segments.

In an embodiment, the aligning of a segment CRC code calculated in reverse order comprises shifting the phase to negative side.

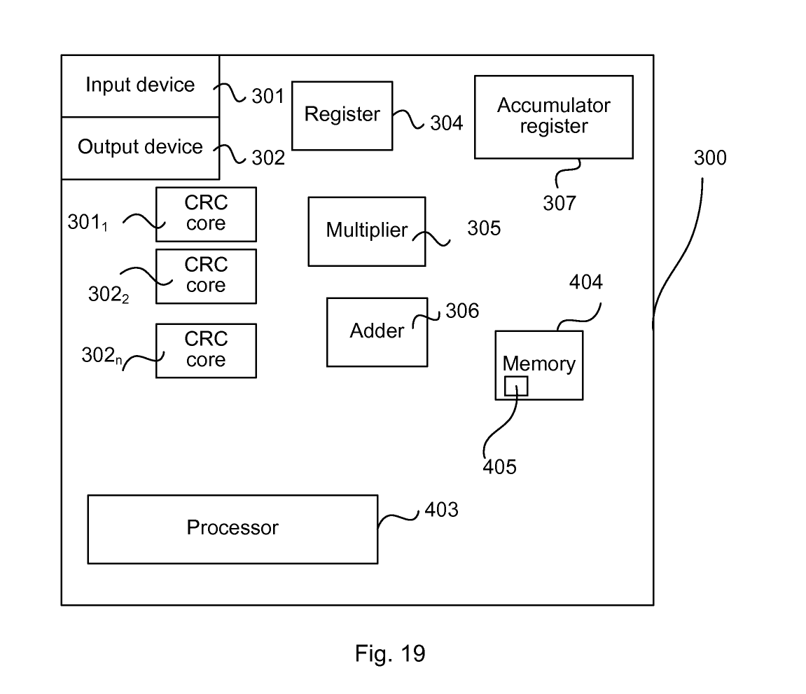

FIG. 19 illustrates schematically a device for implementing embodiments of the present disclosure. The device 300 for calculating CRC codes for a message block may be implemented using software instructions such as computer program executing in a processor and/or using hardware, such as application specific integrated circuits, field programmable gate arrays, discrete logical components, arithmetic logic units, adders, multipliers etc.

The device 300 comprises an input device 301 for receiving for instance a message block or a number of segments of a message block. The input device 301 may comprise an interface for receiving data messages. For example, the input device 301 may comprise processing circuitry adapted to receive a message block by using program code stored in a memory.

The device 300 comprises an output device 302 for outputting data, such as for instance a generated CRC code or a message block. The output device 302 may comprise an interface for outputting data messages.

The device 300 comprises one or more CRC cores 303₁, . . . 303ₙ, each arranged to receive a segment of a message block. Each CRC core 303₁, . . . 303ₙ, may further be arranged to calculate a respective segment CRC code for a segment. Among the CRC cores 303₁, . . . 303ₙ at least one CRC core is arranged to receive and calculate in forward order and at least one CRC core is arranged to receive and calculate in reverse order. It is noted that each or some of the CRC core 303₁, . . . 303ₙ may be arranged to handle reception and calculation in forward order as well as reverse order. The CRC cores 303₁, . . . 303ₙ are arranged to output segments of CRC codes, which may be aligned or unaligned. The output may be provided to a multiplier 305 (described below). The CRC cores 303′, . . . 303ₙ, which may also be denoted CRC engines, may be implemented in hardware and/or software.

The device 300 comprises a register 304, which may be implemented in hardware or software or combinations thereof. The register 304 may for example comprise a linear feedback shift register. Such registers, and in particular function of, are as such well known within the art. However, it is noted that state transitions of the register 304 of the present disclosure differ from prior art.

The device 300 may comprise a multiplier 305, for instance a Galois Field 2 matrix-vector multiplier. Such multiplier 305 may be arranged to receive as input the segment CRC codes from the CRC cores. The output from the multiplier 305 may be input to an adder 306.

The device 300 may comprise one or more adders 306 for vector addition. The adder 306 may for instance be implemented as a digital circuit. The adder 306 may be arranged to receive, as input, the output from the multiplier 305. The adder 306 may provide its output to the register 304.

The device 300 comprises an accumulator register 307 for storing intermediate arithmetic and logic results, e.g. receiving as input the output from the adder 306. Accumulator registers are well known within the art and will not be described in further detail. In this context is noted that the device 300 may comprise additional memory (not illustrated), e.g. a random access memory (RAM) for temporary storage of data processed by the CRC cores. The device 300 may in other embodiments be configured to access an external memory.

The device 300 may be implemented in different ways, i.e. as different embodiments, wherein some embodiments of the device 300 comprises all the described components and other embodiments omits one or more of the described components. In still other embodiments, the device 300 comprises still further components, conventionally used within the field.

It is noted that the device 300 may be arranged to generate CRC codes or to check CRC codes or both generate and check CRC codes.

The device 300 comprises a processor 403 comprising any combination of one or more of a central processing unit (CPU), multiprocessor, microcontroller, digital signal processor (DSP), application specific integrated circuit etc. capable of executing software instructions stored in a memory 404, which can thus be a computer program product 404. The processor 403 can be configured to execute any of the various embodiments of the method 200 as has been described for instance in relation to FIG. 18. The memory 404 can for instance be any combination of random access memory (RAM) and read only memory (ROM), Flash memory, magnetic tape, Compact Disc (CD)-ROM, digital versatile disc (DVD), Blu-ray disc etc. The memory 404 may also comprises persistent storage, which, for example, can be any single one or combination of magnetic memory, optical memory, solid state memory or even remotely mounted memory.

A device 300 is provided for calculating, based on a generator polynomial G(x), a CRC code for a message block. The device 300 may be configured to calculating, based on a generator polynomial G(x), a CRC code for a message block e.g. by comprising one or more processors 403 and memory 404, wherein the memory 404 contains instructions executable by the processor 403, whereby the device 300 is operative to perform e.g. the method 200 as described in various embodiments with reference to FIG. 18.

The device 300 is configured to:
receive n segments of the message block in forward order or in reverse order, wherein at least one segment is received in reverse order,
calculate for each of the n segments a respective segment CRC code based on the generator polynomial G(x), wherein each segment is calculated according to the received order of the segment,
align each of the n segment CRC codes, and
calculate the CRC code for the message block by adding together each of the aligned n segment CRC codes.

In an embodiment, the device 300 is configured to receive by receiving n segments of the message block in forward order or in reverse order, wherein n is equal to or larger than 2 and wherein at least one segment is received in forward order and at least one segment is received in reverse order,

In an embodiment, the device 300 is configured to calculate for each of the n segments a respective segment CRC code, by processing input bits of a segment in forward order or reverse order by obtaining a respective pre-computed matrix.

In an embodiment, the device 300 is configured to align each of the segment CRC code by:
obtaining, from a CRC register, a respective power of a matrix M, the matrix M comprising an L by L constant matrix related to the generator polynomial G(x), wherein L is the length of the CRC code, and
multiplying the respective power of the matrix M with the respective segment CRC code.

In an embodiment, the device 300 is configured to calculate and align in parallel the n segments.

In an embodiment, the device 300 is configured to align a segment CRC code calculated in reverse order by shifting the phase to negative side.

The present disclosure also encompasses a computer program 405 for a device 300 for calculating cyclic redundancy check, CRC, codes, the computer program 405 comprising computer program code, which, when executed on at least one processor 400 on the device 300 causes the device 300 to perform the method 200 as described e.g. in relation to FIG. 18.

The present disclosure also encompasses a computer program product 404 comprising a computer program 405 as above and a computer readable means on which the computer program 405 is stored.

In an aspect, the present disclosure provides a device for calculating cyclic redundancy check, CRC, codes for a message block. The device comprises:
first means for receiving the message block,
second means for receiving a segment of the message block and calculating a respective segment CRC code for a segment, wherein at least one CRC core is arranged to receive and calculate in forward order and at least one CRC core is arranged to receive and calculate in reverse order,
third means for aligning the segment CRC codes, and
fourth means for calculating the CRC code for the message block by adding together each of the aligned n segment CRC codes.

The first means may for instance be an input means such as input means 301 as described in relation to FIG. 19. The second means may for instance comprise the the CRC cores 303₁, . . . 303ₙ as described in relation to FIG. 19. The third means may for instance comprise multiplier means such as e.g. the multiplier 305 as described in relation to FIG. 19. The fourth means may for instance comprise adder means such as the adder 306 as described in relation to FIG. 19.

The device 300 may comprise still additional means form implementing the various embodiments of the present disclosure. The device may be implemented as software instructions such as computer program executing in a processor or by using hardware, such as application specific integrated circuits, field programmable gate arrays, discrete logical components etc., or by any combination of software instructions and hardware.

In the present disclosure, the inverse of the matrix for the state transition of CRC generator is considered and this enables rewinding the state of a CRC generator. For computing the CRC in the reverse order, the state of CRC generator is rewound, i.e. the phase is shifted to negative side, each time receiving the block bit(s), and CRC generator results are unaligned CRC segments. Then the phase shift is performed by multiplying a power of matrix at the final stage. This method is quite different from known existing schemes using reverse polynomial e.g. since the state transitions are different.

Out-of-order processing methodology, multi-bit parallel processing in and multi-core parallel processing are known, wherein the phase is shifted to only positive side. The present disclosure expands these methodologies to the negative side by considering the inverse of the matrix and adds freedom for the input data order.

The present disclosure provides, in different embodiments, a generic calculation method of CRC for reverse order, or mixture of forward and reverse order input.

The invention has mainly been described herein with reference to a few embodiments. However, as is appreciated by a person skilled in the art, other embodiments than the particular ones disclosed herein are equally possible within the scope of the invention, as defined by the appended patent claims.

1: A method performed in a cyclic redundancy check, CRC, device for calculating, based on a generator polynomial G(x), a CRC code for a message block, the method comprising:
receiving n segments of the message block in forward order or in reverse order, wherein at least one segment is received in reverse order,
calculating for each of the n segments a respective segment CRC code based on the generator polynomial G(x), wherein each segment CRC is calculated according to the received order of the segment,
aligning each of the n segment CRC codes, and
calculating the CRC code for the message block by adding together each of the aligned n segment CRC codes.

2: The method as claimed in claim 1, wherein the receiving comprises receiving n segments of the message block in forward order or in reverse order, wherein n is equal to or larger than 2 and wherein at least one segment is received in forward order and at least one segment is received in reverse order.

3: The method as claimed in claim 1, wherein the calculating for each of the n segments a respective segment CRC code, comprises processing input bits of a segment in forward order or reverse order by obtaining a respective pre-computed matrix.

4: The method as claimed in claim 1, wherein the aligning of each of the segment CRC code comprises:
obtaining, from a CRC register, a respective power of a matrix M, the matrix M comprising an L by L constant matrix related to the generator polynomial G(x), wherein L is the length of the CRC code, and
multiplying the respective power of the matrix M with the respective segment CRC code.

5: The method as claimed in claim 1, comprising calculating and aligning in parallel the n segments.

6: The method as claimed in claim 1, wherein the aligning of a segment CRC code calculated in reverse order comprises shifting the phase to negative side.

7: A device for calculating, based on a generator polynomial G(x), a CRC code for a message block, the device being configured to:
receive n segments of the message block in forward order or in reverse order, wherein at least one segment is received in reverse order,
calculate for each of the n segments a respective segment CRC code based on the generator polynomial G(x), wherein each segment is calculated according to the received order of the segment,
align each of the n segment CRC codes, and
calculate the CRC code for the message block by adding together each of the aligned n segment CRC codes.

8: The device as claimed in claim 7, configured to receive by receiving n segments of the message block in forward order or in reverse order, wherein n is equal to or larger than 2 and wherein at least one segment is received in forward order and at least one segment is received in reverse order.

9: The device as claimed in claim 7, configured to calculate for each of the n segments a respective segment CRC code, by processing input bits of a segment in forward order or reverse order by obtaining a respective pre-computed matrix.

10: The device as claimed in claim 2, configured to align each of the segment CRC code by:
obtaining, from a CRC register, a respective power of a matrix M, the matrix M comprising an L by L constant matrix related to the generator polynomial G(x), wherein L is the length of the CRC code, and
multiplying the respective power of the matrix M with the respective segment CRC code.

11: The device as claimed in claim 2, configured to calculate and align in parallel the n segments.

12: The device as claimed in claim 2, configured to align a segment CRC code calculated in reverse order by shifting the phase to negative side.

13: A nontransitory computer readable storage medium comprising a computer program for a device for calculating cyclic redundancy check, CRC, codes, the computer program comprising computer program code, which, when executed on at least one processor on the device causes the device to perform a method for calculating, based on a generator polynomial G(x), a CRC code for a message block, the method comprising:
receiving n segments of the message block in forward order or in reverse order, wherein at least one segment is received in reverse order,
calculating for each of the n segments a respective segment CRC code based on the generator polynomial G(x), wherein each segment CRC is calculated according to the received order of the segment,
aligning each of the n segment CRC codes, and
calculating the CRC code for the message block by adding together each of the aligned n segment CRC codes.

14. (canceled)
